(19) United States
(12) Patent Application Publication
(10) Pub. No.: US 2026/0163242 A1
(43) Pub. Date: Jun. 11, 2026

(54) LOG PERIODIC ANTENNA AND DISPLAY APPARATUS

(71) Applicants: Beijing BOE Technology Development Co., Ltd., Beijing (CN); BOE TECHNOLOGY GROUP CO., LTD., Beijing (CN)

(72) Inventors: Yafei ZHANG, Beijing (CN); Dongdong ZHANG, Beijing (CN); Mengwen JIA, Beijing (CN); Xudong ZHANG, Beijing (CN)

(21) Appl. No.: 18/706,065

(22) PCT Filed: May 19, 2023
(86) PCT No.: PCT/CN2023/095222

§ 371 Date: Apr. 30, 2024

(51) Int. Cl. H01Q 11/10; H01Q 1/12; H10K 59/95

(52) U.S. Cl. CPC H01Q 11/10; H01Q 1/1271; H10K 59/95

(57) ABSTRACT

The present disclosure provides a log periodic antenna, and belongs to the technical field of communications. The log periodic antenna of the present disclosure includes a feed assembly and N radiation structures; where the radiation structures are electrically connected to the feed assembly at M connection nodes, respectively; where N≥3, and M≥3. Distances between the M connection nodes satisfy a periodic variation.

### TECHNICAL FIELD

The present disclosure belongs to the technical field of communications, and specifically relates to a log periodic antenna and a display apparatus.

### BACKGROUND

In the 5G millimeter wave band, the size of the antenna is reduced to millimeter level, and since the antenna has a poor diffraction capability in the millimeter wave band, millimeter waves are generally used in an array. The antenna in package (AiP) technology conforms to the trend of improving the integration level of a silicon-based semiconductor process, and gives consideration to the performance, cost and volume of the antenna, representing a development trend of millimeter wave terminals in recent years. Other types of millimeter wave antennas, such as antennas-in-antenna-in-package (AiAiP), antenna on display (AoD), and antenna in metalframe (AiME), are all millimeter wave solutions currently under exploration, where AoD has notable advantages. Compare with those in the bezel, the back end module and the back shell, AoD has an abundant available area, as well as a relatively simple electromagnetic environment that is difficult to be interfered by other signals. However, since the display screen body (OLED or LCD) is wave-opaque, the application of AoD has to solve at least two problems, one is the gain, and the other one is the radio frequency connection. To achieve higher coverage, the gain of AoD should meet the criteria for spatial coverage. Since AoD is disposed above an emission layer, the antenna is typically meshed to avoid affecting the display effect, which may affect the radiation efficiency. Therefore, how to increase the gain under the limited mesh is a challenge in the application of AoD at present.

### SUMMARY

To solve at least one of the problems in the existing art, the present disclosure provides a log periodic antenna and a display apparatus.

An embodiment of the present disclosure provides a log periodic antenna, including a feed assembly and N radiation structures; where the radiation structures are electrically connected to the feed assembly at M connection nodes, respectively; where N≥3, and M≥3; wherein distances between the M connection nodes satisfy a periodic variation.

Each radiation structure includes a radiation part and a feeder, the radiation part has a notch, and the feeder has one end within the notch and electrically connected to the radiation part, and the other end electrically connected to the feed assembly.

The notch has a first side electrically connected to the feeder, and a second side and a third side connected to two ends of the first side, and the second side and the third side have the same extending direction as the feeder, and are perpendicular to the first side.

The radiation part has a generally regular octagonal outline.

The feed assembly has a first side and a second side opposite to each other, and the radiation structures are connected to both the first side and the second side of the feed assembly.

Each radiation structure includes a radiation part and a feeder, and the radiation part is electrically connected to the feed assembly by the feeder; and
respective radiation structures are connected to the feed assembly at different connection nodes, and radiation parts of the respective radiation structures have gradually reduced sizes in a direction away from a feed port of the feed assembly, which gradually reduced sizes satisfy a periodic variation.

The radiation structures connected to the first side and the second side of the feed assembly are arranged in one-to-one correspondence, and the radiation structures in correspondence are connected to the feed assembly at the same connection node; each radiation structure includes a radiation part and a feeder, and the radiation part is electrically connected to the feed assembly by the feeder; and
radiation parts of the radiation structures in correspondence have the same size; radiation parts of the respective radiation structures connected to the first side of the feed assembly have gradually reduced sizes in a direction away from a feed port of the feed assembly, which satisfy a periodic variation; and radiation parts of the respective radiation structures connected to the second side of the feed assembly have gradually reduced sizes in a direction away from a feed port of the feed assembly, which gradually reduced sizes satisfy a periodic variation.

The feeder has a single extending direction which is intersected with an extending direction of the feed assembly.

The feeder includes a first sub-feeder and a second sub-feeder which have different extending directions; wherein a first end of the first sub-feeder is connected to the feed assembly, a second end of the first sub-feeder is connected to a first end of the second sub-feeder, and a second end of the second sub-feeder is connected to the radiation part.

The feed assembly has a first side and a second side opposite to each other and the radiation structures are connected to either the first side or the second side of the feed assembly.

Each radiation structure includes a radiation part and a feeder, and the radiation part is electrically connected to the feed assembly by the feeder; and
respective radiation structures are connected to the feed assembly at different connection nodes, and radiation parts of the respective radiation structures have gradually reduced sizes in a direction away from a feed port of the feed assembly, which gradually reduced sizes satisfy a periodic variation.

Each radiation structure includes a radiation part and a feeder, and the radiation part is electrically connected to the feed assembly by the feeder; and
every two adjacent radiation structures form a group in which the feeder of each radiation structure includes a first sub-feeder and a second sub-feeder which have different extending directions; a first end of the first sub-feeder is connected to the feed assembly, a second end of the first sub-feeder is connected to a first end of the second sub-feeder, and a second end of the second sub-feeder is connected to the radiation part; and the two radiation structures share one first sub-feeder, second sub-feeders of the two radiation structures are symmetrically arranged taking an extending direction of the first sub-feeder as an axis of symmetry, and radiation parts of the two radiation structures have the same size; and
radiation parts of respective groups of radiation structures have gradually reduced sizes in a direction away from a feed port of the feed assembly, which gradually reduced sizes satisfy a periodic variation.

First sub-feeders of the respective groups of radiation structures have gradually increased lengths in a direction away from the feed port of the feed assembly.

A feed port of the feed assembly includes a first sub-structure, a second sub-structure, and a third sub-structure connected in sequence; and the second sub-structure is configured to match an impedance of the first sub-structure with an impedance of the third sub-structure.

An embodiment of the present disclosure provides a display apparatus, including a display module, and an antenna module on a light-emitting surface side of the display module; wherein the antenna module includes at least one log periodic antenna as described above.

The antenna module includes a radiation layer; wherein the radiation layer has a metal mesh structure, and the log periodic antenna is in the radiation layer.

The radiation layer further includes a redundant radiation structure.

The display apparatus further includes a polarizer, wherein the antenna module is on a side of the polarizer close to the display module.

The display apparatus further includes a touch module between the display module and the antenna module.

The display module is an organic light-emitting diode display module.

### BRIEF DESCRIPTION OF DRAWINGS

FIG. 1 is a schematic diagram of film layers in a display apparatus according to an embodiment of the present disclosure.

FIG. 2 is a top view of a log periodic antenna according to an embodiment of the present disclosure.

FIG. 3 is a top view of a radiation layer according to an embodiment of the present disclosure.

FIG. 4 is a top view of a radiation structure according to an embodiment of the present disclosure.

FIG. 5 is a top view of another log periodic antenna according to an embodiment of the present disclosure.

FIG. 6 is a graph of gain for each radiation structure in FIG. 5.

FIG. 7 is a graph of S parameter for each radiation structure in FIG. 5.

FIG. 8 is a schematic diagram of a feed port for a feed assembly according to an embodiment of the present disclosure.

FIG. 9 is a graph of gain for a log periodic antenna in a first example according to an embodiment of the present disclosure.

FIG. 10 is a graph of S parameter for a log periodic antenna in the first example according to an embodiment of the present disclosure.

FIG. 11 is a top view of an antenna module in the first example according to an embodiment of the present disclosure.

FIG. 12 is a graph of gain for the antenna module in the first example according to an embodiment of the present disclosure.

FIG. 13 is a graph of S parameter for the antenna module in the first example according to an embodiment of the present disclosure.

FIG. 14 is a top view of a log periodic antenna in a second example according to an embodiment of the present disclosure.

FIG. 15 is a graph of gain for a log periodic antenna in the second example according to an embodiment of the present disclosure.

FIG. 16 is a graph of S parameter for a log periodic antenna in the second example according to an embodiment of the present disclosure.

FIG. 17 is a top view of an antenna module in the second example according to an embodiment of the present disclosure.

FIG. 18 is a graph of gain for the antenna module in the second example according to an embodiment of the present disclosure.

FIG. 19 is a graph of S parameter for the antenna module in the second example according to an embodiment of the present disclosure.

FIG. 20 is a top view of a log periodic antenna in a third example according to an embodiment of the present disclosure.

FIG. 21 is a graph of gain for a log periodic antenna in the third example according to an embodiment of the present disclosure (three radiation structures vs. five radiation structures).

FIG. 22 is a graph of S parameter for a log periodic antenna in the third example according to an embodiment of the present disclosure (three radiation structures vs. five radiation structures).

FIG. 23 is a top view of an antenna module in the third example according to an embodiment of the present disclosure.

FIG. 24 is a top view of a log periodic antenna in a fourth example according to an embodiment of the present disclosure.

FIG. 25 is a top view of another antenna in the fourth example according to an embodiment of the present disclosure.

FIG. 26 is a top view of yet another antenna in the fourth example according to an embodiment of the present disclosure.

FIG. 27 shows gain curves for the antennas in FIGS. 25 and 26 according to an embodiment of the present disclosure.

FIG. 28 shows S parameter curves for the antennas in FIGS. 25 and 26 according to an embodiment of the present disclosure.

FIG. 29 is a top view of an antenna module in the fourth example according to an embodiment of the present disclosure.

FIG. 30 is a graph of gain for the antenna module in the fourth example according to an embodiment of the present disclosure.

FIG. 31 is a graph of S parameter for the antenna module in the fourth example according to an embodiment of the present disclosure.

FIG. 32 is a top view of a log periodic antenna in a fifth example according to an embodiment of the present disclosure.

FIG. 33 is a top view of a log periodic antenna in the fifth example according to an embodiment of the present disclosure.

FIG. 34 is a graph of gain for a log periodic antenna in the fifth example according to an embodiment of the present disclosure.

FIG. 35 is a top view of a log periodic antenna in a sixth example according to an embodiment of the present disclosure.

FIG. 36 is a graph of gain for a log periodic antenna in the sixth example according to an embodiment of the present disclosure.

FIG. 37 shows an S parameter for a log periodic antenna in the sixth example according to an embodiment of the present disclosure.

FIG. 38 is a top view of a log periodic antenna in a seventh example according to an embodiment of the present disclosure.

FIG. 39 is a top view of another log periodic antenna in the seventh example according to an embodiment of the present disclosure.

FIG. 40 is a top view of the log periodic antenna in FIG. 40 according to an embodiment of the present disclosure.

FIG. 41 is a graph of gain for the log periodic antenna in FIG. 40 according to an embodiment of the present disclosure.

### DETAIL DESCRIPTION OF EMBODIMENTS

To improve understanding of the technical solution of the present disclosure for those skilled in the art, the present disclosure will be described in detail with reference to accompanying drawings and specific implementations.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprising” or “including” or the like means that the element or item preceding the word contains elements or items that appear after the word or equivalents thereof, but does not exclude other elements or items. The terms “connected” or “coupled” and the like are not restricted to physical or mechanical connections, but may include electrical connections, whether direct or indirect. The words “upper”, “lower”, “left”, “right”, and the like are merely used to indicate a relative positional relationship, and when an absolute position of the described object is changed, the relative positional relationship may be changed accordingly.

Due to a simple structure, impedance matching and a “frequency independent” pattern, the log periodic antenna is widely used in many fields of communications, such as broadcasting, television and the like in short wave, ultrashort wave and even microwave frequency bands. An embodiment of the present disclosure provides a technical solution of applying a log periodic antenna on display.

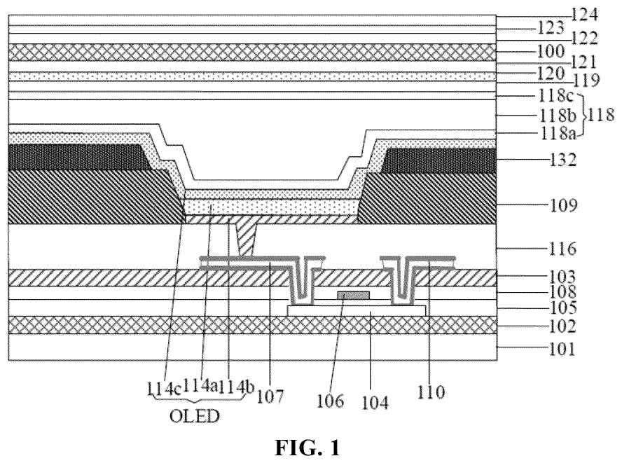

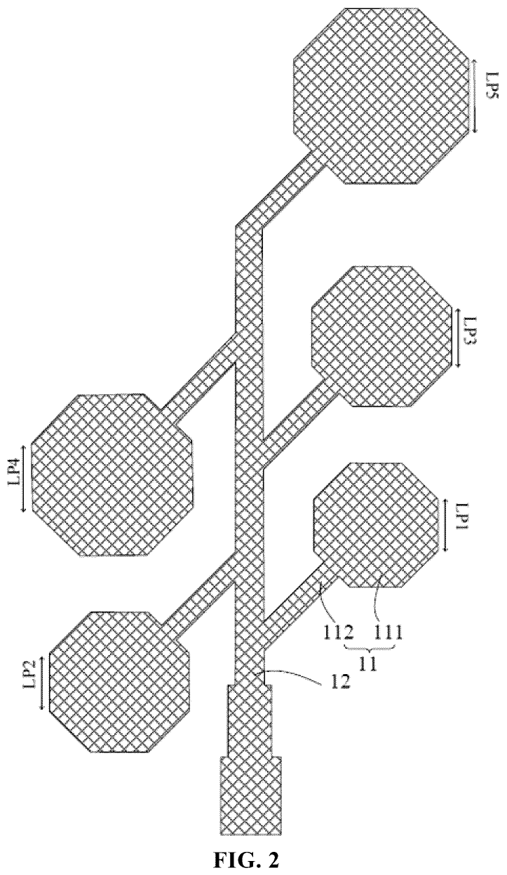

Before describing the log periodic antenna in the embodiments of the present disclosure, it should be noted that the log periodic antenna in the embodiments of the present disclosure may be integrated in a display apparatus. FIG. 1 is a schematic diagram of film layers in a display apparatus according to an embodiment of the present disclosure; and FIG. 2 is a top view of a log periodic antenna according to an embodiment of the present disclosure. As shown in FIGS. 1 and 2, specifically, the display apparatus may include a display module and an antenna module on a light-emitting surface side of the display module. The antenna module may include at least one log periodic antenna in the embodiments of the present disclosure. In this case, there is no need to provide a separate ground layer in the log periodic antenna, and a conductor line layer in the display module may be used as a reference ground for the log periodic antenna. Apparently, the log periodic antenna in the embodiments of the present disclosure is not limited to be applied to a display apparatus, and may also be applied to other electronic devices. The embodiments of the present disclosure are described merely taking the log periodic antenna applied to a display apparatus as an example, but this does not form any limitation to the scope of the embodiments of the present disclosure.

Referring to FIG. 2, a log periodic antenna includes a feed assembly 12 and N radiation structures 11, where N≥3, and each radiation structure 11 includes a feeder 112 and a radiation part 111 electrically connected to the feeder 112. The feeder 112 is further connected to a feed assembly 12. In the log periodic antenna, radiation parts 112 of the respective radiation structures 11 connected to the feed assembly 12 in sequence have sizes varying periodically in a direction away from a feed port of the feed assembly 12. It should be noted here that if the radiation part 111 has a regular octagonal outline, the size of the radiation part 111 is determined by a side length thereof, and the sizes of the radiation parts varying periodically means that side lengths of the radiation parts vary periodically. For example: the feed assembly 12 is connected to five radiation structures 11 in sequence in a direction away from the feed port of the feed assembly 12. The side lengths of the first to fifth radiation parts are represented by LP1, LP2, LP3, LP4 and LP5, respectively; and given a scale factor t, LP2=t*LP1; LP3=t*LP2; LP4=t*LP3; and LP5=t*LP4.

In some examples, with continued reference to FIG. 1, in the embodiments of the present disclosure, the display module in the display apparatus may be an organic light-emitting diode display module, or a liquid crystal display module, and the embodiments of the present disclosure are described by taking the display module being an organic light-emitting diode as an example. Specifically, the organic light-emitting diode display module may include a base substrate 101, a plurality of pixel units on the base substrate 101, and an encapsulation layer 118 on a side of the pixel units away from the base substrate. Each pixel unit includes a pixel driver circuit and an organic light-emitting diode OLED. The pixel driver circuit is formed by connecting electrical components such as thin film transistors and storage capacitors. FIG. 1 merely schematically shows a thin film transistor electrically connected to the organic light-emitting diode OLED, and since other thin film transistors have the same or substantially the same film layer structure as this thin film transistor, the following description of film layers will be given by merely taking one thin film transistor as an example. Referring to FIG. 1, the thin film transistor may be a top gate type which may include an active layer 104, a first gate insulation layer 105, a gate 106, a second gate insulation layer 108, an interlayer dielectric layer 103, a source 110, and a drain 107. Specifically, the active layer 104 may be formed on a buffer layer 102, the first gate insulation layer 105 covers the buffer layer 102 and the active layer 104, the gate 106 is formed on a side of the first gate insulation layer 105 away from the active layer 104, the second gate insulation layer 108 covers the gate 106 and the first gate insulation layer 105, the interlayer dielectric layer 103 covers the second gate insulation layer 108, the source 110 and the drain 107 are formed on a side of the interlayer dielectric layer 103 away from the base substrate and located on two opposite sides of the gate 106, respectively, and the source 110 and the drain 107 may each contact two opposite sides of the active layer 104 through vias (e.g., metal vias). It will be appreciated that the thin film transistor may alternatively be a bottom gate type. A planarization layer 116 may be further formed between the thin film transistor and the organic light-emitting diode. The planarization layer 116 may have a single-layer structure or a multi-layer structure. The planarization layer 116 is typically made of an organic material, for example: photoresist, acrylic-based polymers, silicon-based polymers, or the like. As shown in FIG. 1, the planarization layer 116 is located on a side of the source 110 and the drain 107 of the thin film transistor away from the interlayer dielectric layer. A first electrode 114b of the organic light-emitting diode OLED may be electrically connected to the drain 107 through a metal via, and the first electrode 114b may be an anode which may be made of indium tin oxide (ITO), indium zinc oxide (IZO), zinc oxide (ZnO), or the like. The pixel defining layer 109 may cover the planarization layer 116, and may be made of an organic material, for example: an organic material such as photoresist, and the pixel defining layer 109 has a pixel opening exposing the first electrode 114b. An emission layer 114a of the organic light-emitting diode OLED is located within the pixel opening and formed on the first electrode 114b. The emission layer 114a may include a small molecule organic material or a polymer molecule organic material, which may be a fluorescent emitting material or a phosphorescent emitting material that emits red light, green light, blue light, or white light, or the like. In addition, according to different practical needs and in different examples, the emission layer 114a may further include an electron injection layer, an electron transport layer, a hole injection layer, a hole transport layer, and other functional layers. A second electrode 114c of the organic light-emitting diode covers the emission layer 114a, and has an opposite polarity to the first electrode 114b. The second electrode 114c may be a cathode made of a metal material, such as lithium (Li), aluminum (Al), magnesium (Mg) or silver (Ag). The encapsulation layer 118 is located on a side of the organic light-emitting diode away from the thin film transistor, and may include a first inorganic encapsulation film layer 118a, an organic encapsulation film layer 118b, and a second inorganic encapsulation film layer 118c sequentially arranged in a stack. The first inorganic encapsulation film layer 118a and the second inorganic encapsulation film layer 118c are configured to prevent water and oxygen from entering the emission layer 114a. The first inorganic encapsulation film layer 118a and the second inorganic encapsulation film layer 118c may be made of an inorganic material such as silicon nitride or silicon oxide. The organic encapsulation film layer 118b is configured for planarization to facilitate manufacturing of the second inorganic encapsulation film layer 118c, and may be made of acrylic-based polymers, silicon-based polymers, or other materials.

In some examples, with continued reference to FIG. 1, the display apparatus in the embodiments of the present disclosure may be a touch display apparatus, in which case, a touch module 120 is further provided on a side of the encapsulation layer away from the organic light-emitting device. A buffer layer 119 may be disposed between the touch module 120 and the encapsulation layer 118. The touch module 120 may include multiple rows of touch electrodes and multiple columns of sensing electrodes. Each row of touch electrodes includes a plurality of touch electrode blocks and connection parts for connecting adjacent touch electrode blocks; and each column of sensing electrodes includes a plurality of sensing electrode blocks and bridge parts for connecting adjacent sensing electrode blocks. In some examples, the touch electrode blocks, the connection parts, and the sensing electrode blocks are located in the same layer and disposed on a side of the buffer layer 119 away from the encapsulation layer 118, while the bridge parts are located on a side of the layer where the touch electrode blocks, the connection parts, and the sensing electrode blocks are located away from the buffer layer 119, and arranged crosswise with the connection parts. It will be appreciated that the bridge parts are isolated from the connection parts by an insulation layer to avoid short circuit.

Further, where the display apparatus has the touch module 120, the log periodic antenna in the antenna module may be disposed on a side of the touch module 120 away from the encapsulation layer 118. The log periodic antenna may be fixed to the touch module by a first adhesive layer 121. Specifically, the first adhesive layer may include an optically clear adhesive (OCA). Furthermore, the display apparatus further includes a polarizer 122 on a side of the log periodic antenna away from the touch module 120. Apparently, a cover glass 124 is further provided on a side of the polarizer 122 away from the log periodic antenna to serve as a protective glass. The polarizer is bonded to the cover glass by a second adhesive layer 123 which may be specifically an optically clear adhesive.

It should be noted that the touch module 120 in the display apparatus may be omitted in the embodiments of the present disclosure, in which case the log periodic antenna 100 is disposed between the encapsulation layer 118 and the polarizer 123.

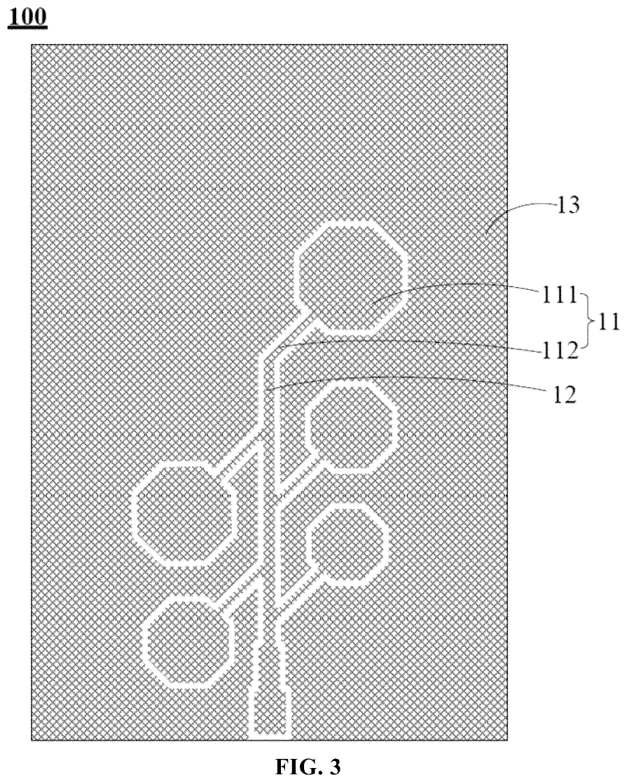

In some examples, FIG. 3 is a top view of a radiation layer according to an embodiment of the present disclosure. Referring to FIG. 3, a log periodic antenna in an embodiment of the present disclosure includes a radiation layer 100 which may have a metal mesh structure. A feed assembly 12 of the log periodic antenna and a radiation structure 11 electrically connected to the feed assembly 12 are located in the radiation layer 100. In this manner, the light transmittance can be effectively improved. Meanwhile, Moire can be reduced by reasonably arranging the period and angle of the metal mesh structure.

Further, the metal mesh structure may include a plurality of first metal lines and a plurality of second metal lines arranged crosswise with the first metal lines. The first metal lines are arranged side by side in a first direction and extend in a second direction; while the second metal lines are arranged side by side in the first direction and extend in a third direction. In an embodiment of the present disclosure, each layer of the adopted metal mesh structure has a light transmittance of about 70% to 88%. The extending directions of the first metal lines and the second metal lines in the metal mesh structure may be perpendicular to each other, and in this case, square or rectangular hollowed-out portions are formed. Apparently, the extending directions of the first metal lines and the second metal lines in the metal mesh structure may be not perpendicular to each other. For example: the extending directions of the first metal lines and the second metal lines form an angle of 45°, and in this case, diamond hollowed-out portions are formed. For example: the first metal lines and the second metal lines each have a line width W1 of about 1 μm to 30 μm, a line spacing W2 of about 50 μm to 250 μm, and a line thickness of about 0.5 μm to 10 μm. In the following examples of the embodiments of the present disclosure, the radiation structure 11 and the feed assembly 12 both adopt a metal mesh structure, and in the simulation experiments of the following examples, the case where the first metal line and the second metal line each have a line width and a line thickness of 1.5 μm*3 μm is taken as an example for illustration.

Furthermore, in addition to the above structures, the radiation layer in the embodiments of the present disclosure further includes a redundant radiation structure 13 disconnected from the radiation structure 11, so that the display uniformity of the display apparatus is increased. In this case, the radiation structure 11 and the redundant radiation structure 13 may be formed by one patterning process, and a whole layer of first metal lines and second metal lines arranged crosswise may be formed and then disconnected to form the radiation structure 11 and the redundant radiation structure 13. In some examples, each disconnection between the first metal lines and the second metal lines in the first radiation layer has a width of about 1 μm to 30 μm, but apparently, the width of the disconnection may be specifically defined according to the radiation requirements of the antenna.

Furthermore, in addition to the radiation layer, the log periodic antenna further includes a base material layer, a bonding layer, a protective layer, and a dielectric substrate. The radiation layer is integrated on the dielectric substrate. Specifically, a slot is formed in the dielectric substrate, in which the radiation layer may be formed by electroplating a seed layer, the protective layer covers a side of the dielectric substrate, and the base material layer is connected to the protective layer through the bonding layer. The base material layer is a flexible film made of a material including, but not limited to, polyethylene terephthalate (PET), polyimide (PI), or the like. The protective layer may be an inorganic insulation layer formed of silicon nitride (SiNx), or an inorganic insulation layer formed of silicon oxide (SiO₂), or a combination film layer of several SiNx inorganic insulation layers and SiO₂ inorganic insulation layers in a stack. The dielectric substrate may be a glass substrate. The adhesive layer may include an optically clear adhesive.

In some examples, referring to FIG. 2, each radiation structure 11 includes a radiation part 111 configured mainly for electromagnetic wave radiation, and a feeder 112 electrically connecting the radiation part 111 to the feed assembly 12. The radiation part 111 may have a regular or substantially regular octagonal outline. It should be noted that the substantially regular octagonal outline refers to an outline in which one or several sides of the original octagonal shape are bent, but the main structure is still an octagonal shape. Apparently, the radiation part 111 may have other shapes of outlines, such as a square shape, a rectangular shape, a regular hexagonal shape, or the like. In the embodiments of the present disclosure, the radiation part 111 of an octagonal or substantially octagonal shape is taken as an example for illustration, the only reason for which is that it is more similar to a rectangular microstrip antenna, and when an antenna array is formed, the structure can be more compact, and the distance between antennas can be further reduced.

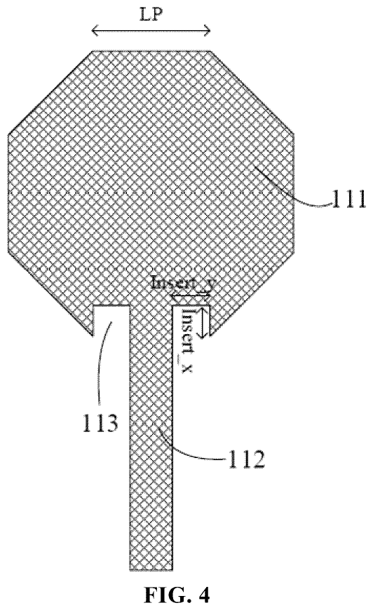

Further, FIG. 4 is a top view of a radiation structure according to an embodiment of the present disclosure. Referring to FIG. 4, a notch 113 is provided in the radiation part 111, and the feeder 112 has one end located within the notch 113 and electrically connected to the radiation part 111, and the other end electrically connected to the feed assembly 12. In the embodiments of the present disclosure, by providing the notch 113 in the radiation part 111 and connecting the feeder 112 to the notch 113, reflection generated at the connection between the feeder 112 and the radiation part 111 is reduced.

Furthermore, the notch 113 has a first side electrically connected to the feeder 112, and a second side and a third side connected to two ends of the first side. The second side and the third side have the same extending direction as the feeder 112, and are disposed perpendicular to the first side. In other words, the notch 113 is a rectangular notch 113, and in this manner, the S parameter can be improved.

Specifically, the regular octagonal radiation part 111 has a side length LP (at a side without the notch 113), while the feeder 112 has a length LS. A distance from the connection between the feeder 112 and the first side of the notch 113 to the second side of the notch 113 is insert_y, while the second side and the third side each have a length insert_x. The result of parameter scanning of sizes of the regular octagonal shape shows that the gain and the S parameter are mainly affected by LP and insert_x, which determine the final S parameter and gain, and different values of insert_y have less effect on the S parameter and the gain. Although LS nearly has no influence on the S parameter and the gain within the unit, it may affect a phase of the radiation unit in a combined structure of different units, and is therefore also a key parameter.

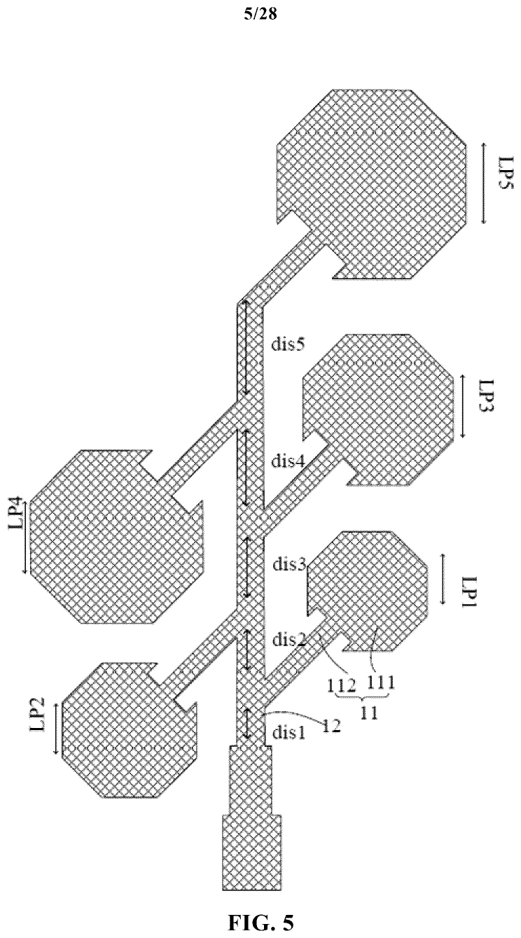

The S parameter and the gain of the radiation structure 11 are affected by the three parameters, i.e., LP, insert_x, and LS, which may be scaled according to a certain rule to obtain S parameters and gains under different frequencies. A scale factor t is added, and t being 1.04 is taken as an example for illustration. FIG. 5 is a top view of another log periodic antenna according to an embodiment of the present disclosure. Referring to FIG. 5, five radiation structures 11 are included, and in the first to fifth radiation structures 11, LS is represented by LS1, LS2, LS3, len_strip4 and len_strip5, respectively, and insert_x is represented by insert_x1, insert_x2, insert_x3, insert_x4 and insert_x5, respectively.

$$L P 2 = t * L P 1 ; insert\_x 2 = t * insert\_x 1 ; L S 2 = t * L S 1 ; L P 3 = t * L P 2 ; insert\_x 3 = t * insert\_x 2 ; and L S 3 = t * L S 2 ;$$

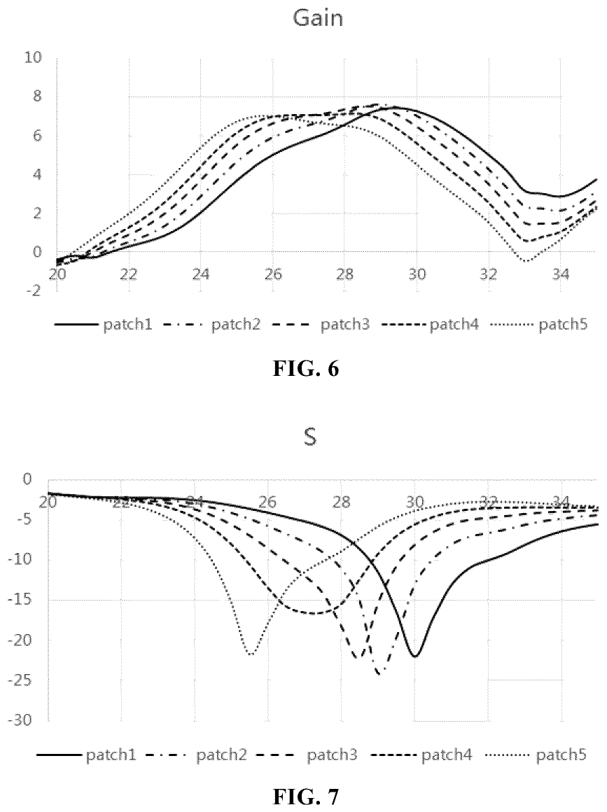

so on and so forth, so that the S parameters and the gains of octagonal radiation parts 111 with different sizes are obtained. FIG. 6 is a graph of gain for each radiation structure in FIG. 5; and FIG. 7 is a graph of S parameter for each radiation structure in FIG. 5. As shown in FIGS. 6 and 7, different units are interrelated. With these radiation structures 11, a combined radiation structure 11 with S parameter and gain in a broadband is obtained.

In some examples, in the log periodic antenna according to the embodiments of the present disclosure, N radiation structures 11 are connected to the feed assembly 12 at M connection nodes, where M≥3. Distances between the M connection nodes satisfy a periodic variation. M may be equal to or different from N, as will be described below with reference to specific examples.

First example: Referring to FIG. 5, in a log periodic antenna according to this example, each radiation structure 11 is connected to the feed assembly 12 at a different connection node. In this example, the case where M=5 and N=5 is taken as an example for illustration. The feed assembly 12 includes a first side and a second side disposed opposite to each other, two radiation structures 11 are connected to the first side, and three radiation structures 11 are connected to the second side. In a direction away from a feed port of the feed assembly 12, feeders 112 of first to fifth radiation structures 11 are sequentially connected to the feed assembly 12, and staggered on the first side and the second side of the feed assembly 12. The feeders of the first to fifth radiation structures 11 are connected to the feed assembly 12 at a first node, a second node, a third node, a fourth node, and a fifth node, respectively. A distance from the first node to the feed port is denoted as a first distance dis1, a distance from the first node to the second node is denoted as a second distance dis2, a distance from the second node to the third node is denoted as a third distance dis3, a distance from the third node to the fourth node is denoted as a fourth distance dis4, and a distance from the fourth node to the fifth node is denoted as a fifth distance dis5. A scale factor t is added, where dis2=t*dis1, dis3=t*dis2, dis4=t*dis3 and dis5=t*dis4. Two types of log periodic antennas are simulated, one with distances between connection nodes of the feeders 112 of the radiation structures 11 and the feed assembly 12 vary periodically, and the other with equal distances between connection nodes of the feeders 112 of the radiation structures 11 and the feed assembly 12, and the former obtains an overall increase of about 0.5 dBi in the gain of the log periodic antenna, and the S parameter is also relatively good. Moreover, with the distances between the connection nodes of the feeders 112 of the radiation structures 11 and the feed assembly 12 vary periodically, different radiation structures 11 can work at different resonance frequencies, which can ensure that all the radiation structures 11 have substantially a synchronous phase at resonance, and thereby generate a superposition effect on the synthetic gain and pattern.

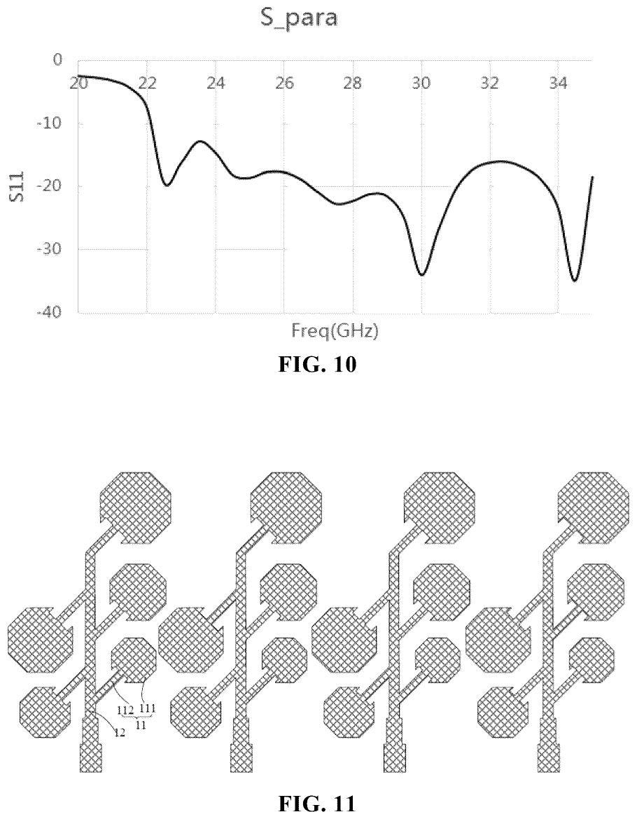

In addition, compared with an antenna with a single radiation structure 11, the log periodic antenna with a plurality of radiation structures 11 has improved S parameter and gain, which is equivalent to the combination effect of five octagonal units, so that the bandwidth is expanded, the gain is increased, and the log periodic antenna is more suitable to be used as a wideband antenna. FIG. 9 is a graph of gain for a log periodic antenna in a first example according to an embodiment of the present disclosure; and FIG. 10 is a graph of S parameter for a log periodic antenna in the first example according to an embodiment of the present disclosure. The simulation results in FIGS. 9 and 10 show that the S parameter has an echo less than 10 dB and a gain greater than 8.5 dB in the frequency band of 24.25 GHz to 29.5 GHz. With continued reference to FIG. 5, the feeder 112 of each radiation structure 11 extends in a single direction and forms an angle of 45° with an extending direction of the feed assembly 12, so that the polarization direction of the log periodic antenna in this example is 45° polarization.

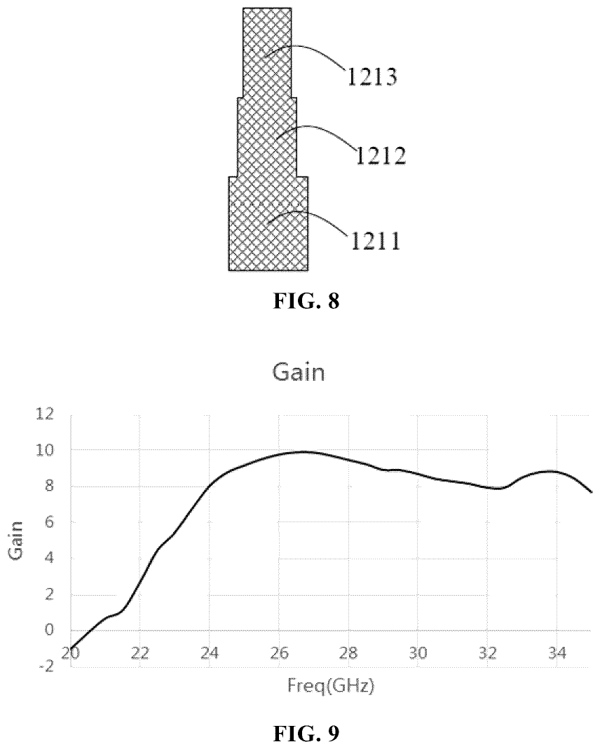

In some examples, FIG. 8 is a schematic diagram of a feed port for a feed assembly according to an embodiment of the present disclosure. As shown in FIG. 8, the feed assembly 12 includes a first sub-structure 1211, a second sub-structure 1212, and a third sub-structure 1213 connected in sequence. The second sub-structure 1212 is configured to match an impedance of the first sub-structure 1211 with an impedance of the third sub-structure 1213, and the impedances of the three sub-structures are denoted by Zin, Ztrans and ZL, respectively. For example: in practical use, a feed impedance at a radio frequency front end is 50 ohms, i.e., Zin=50 ohms, and depending on different stacked structures, an impedance of the radiation structure 11 is not necessarily 50 ohms, so that certain impedance matching is required, and the impedance ZL of the radiation structure 11 is matched with the 50 ohms of Zin by a quarter-wave matching segment. Since only antenna simulation is performed at present and radio frequency front end links are not involved, and the impedance is not a critical factor, ZL=Ztrans=Zin is adopted in the simulation, while impedance matching adjustment is required in practice.

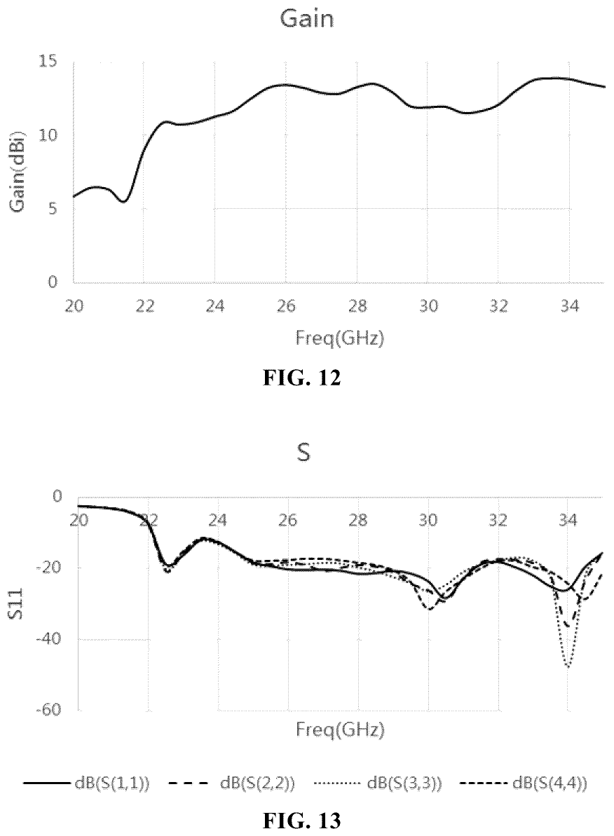

In some examples, FIG. 11 is a top view of an antenna module in the first example according to an embodiment of the present disclosure. As shown in FIG. 11, when the log periodic antenna is applied to an antenna module, the antenna module may include a plurality of log periodic antennas, and in a case where the antenna module includes 1*4 log periodic antennas, the S parameter may be improved to about 14 dB. FIG. 12 is a graph of gain for the antenna module in the first example according to an embodiment of the present disclosure; and FIG. 13 is a graph of S parameter for the antenna module in the first example according to an embodiment of the present disclosure. The simulation results are shown in FIGS. 12 and 13.

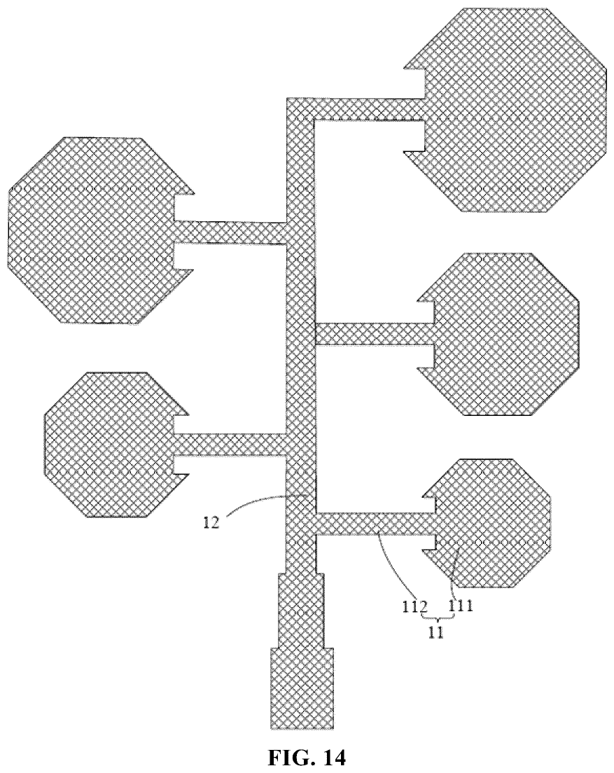

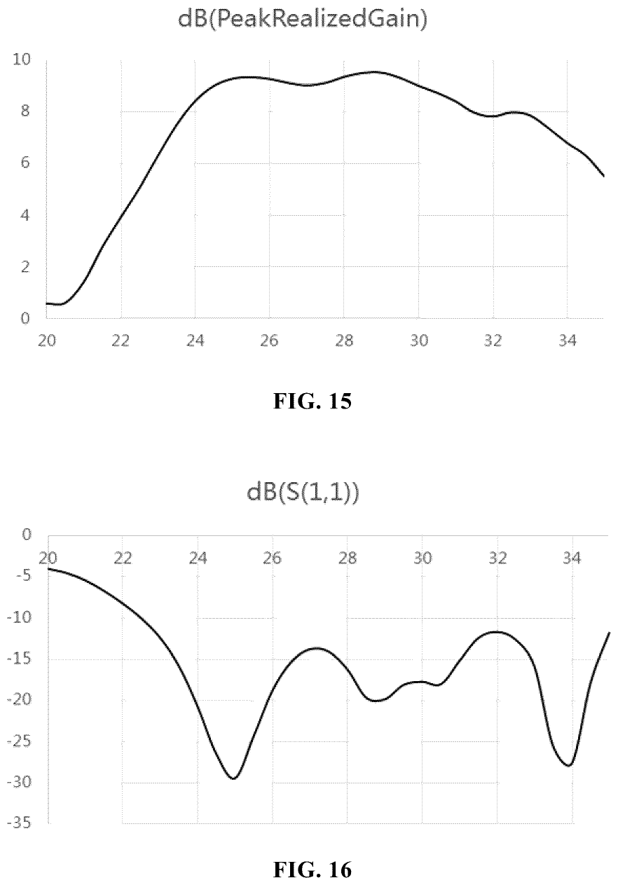

Second example: FIG. 14 is a top view of a log periodic antenna in a second example according to an embodiment of the present disclosure. As shown in FIG. 14, the log periodic antenna in this example has substantially the same structure as the log periodic antenna in the first example, except that the feeder 112 of each radiation structure 11 in the log periodic antenna has an extending direction perpendicular to the extending direction of the feed assembly 12, and this structure only results in a polarization direction of the log periodic antenna different from the 45° polarization direction in the first example, that is, the polarization direction of the log periodic antenna in this example is a vertical polarization direction. FIG. 15 is a graph of gain for a log periodic antenna in the second example according to an embodiment of the present disclosure; and FIG. 16 is a graph of S parameter for a log periodic antenna in the second example according to an embodiment of the present disclosure.

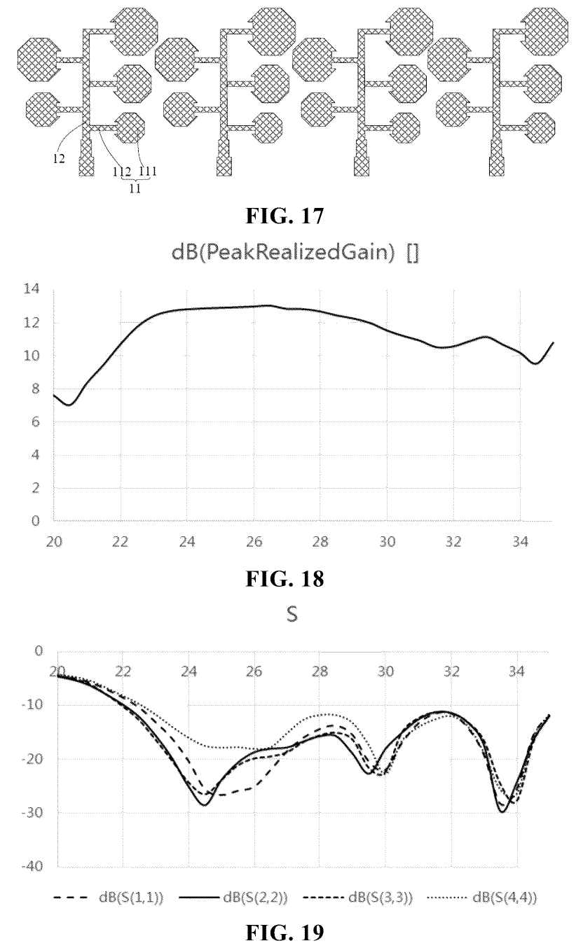

In some examples, FIG. 17 is a top view of an antenna module in the second example according to an embodiment of the present disclosure. As shown in FIG. 17, when the log periodic antenna is applied to an antenna module, the antenna module may include a plurality of log periodic antennas, and in a case where the antenna module includes 1*4 log periodic antennas, since the feeder 112 is perpendicular to the feed assembly 12 in this example, instead of 45° inclined from the feed assembly 12 as in the first example, a distance between the log periodic antennas are notably increased compared with the first example. It should be noted that the distance between the log periodic antennas should not exceed half wavelength of a center frequency, so as to reduce the risk of generating a larger side lobe and affecting the synthetic pattern. FIG. 18 is a graph of gain for the antenna module in the second example according to an embodiment of the present disclosure; and FIG. 19 is a graph of S parameter for the antenna module in the second example according to an embodiment of the present disclosure. The simulation results are shown in FIGS. 18 and 19.

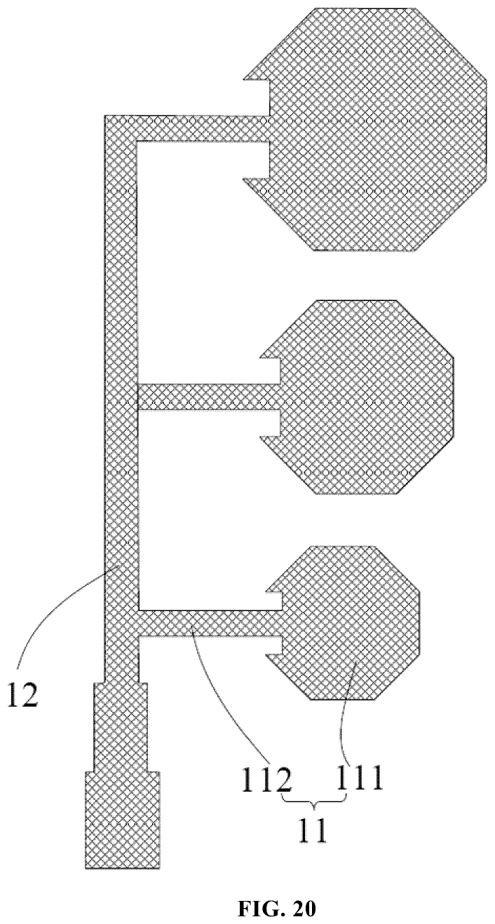

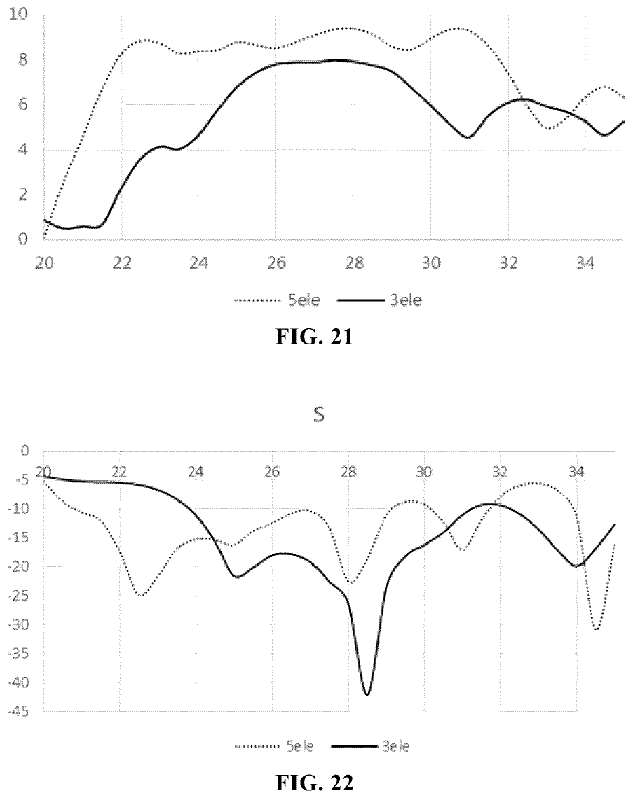

Third example: FIG. 20 is a top view of a log periodic antenna in a third example according to an embodiment of the present disclosure. As shown in FIG. 20, the log periodic antenna in this example has substantially the same structure as the log periodic antenna in the second example, except that in this example, the radiation structures 11 are connected to only one of the first side or the second side of the feed assembly 12, and FIG. 20 only takes the case where three radiation structures 11 are connected to the second side of the feed assembly 12 as an example for illustration. FIG. 21 is a graph of gain for a log periodic antenna in the third example according to an embodiment of the present disclosure (three radiation structures vs. five radiation structures); and FIG. 22 is a graph of S parameter for a log periodic antenna in the third example according to an embodiment of the present disclosure (three radiation structures vs. five radiation structures). As shown in FIGS. 21 and 22, in this case, compared with the log periodic antenna in the second example, the S parameter is below −10 dB in both cases, while the gain, as well as the gain bandwidth, of the log periodic antenna in the second example is significantly higher than that of the log periodic antenna in this example. It can be seen that the increase in the number of the radiation structures 11 can significantly improve the bandwidth. The antenna having five radiation structures can have a gain up to around 14 dBi.

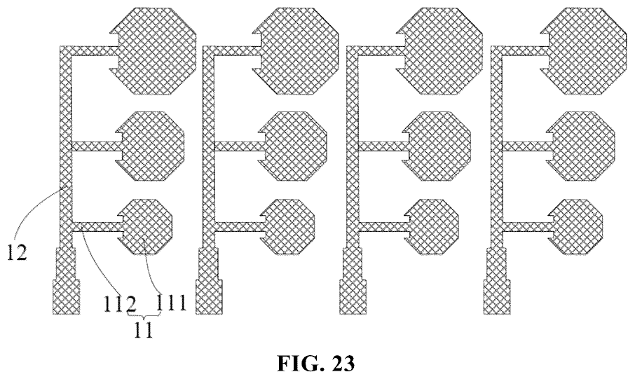

In some examples, FIG. 23 is a top view of an antenna module in the third example according to an embodiment of the present disclosure. As shown in FIG. 23, when the log periodic antenna is applied to an antenna module, the antenna module may include a plurality of log periodic antennas, and the case where the antenna module includes 1*4 log periodic antennas is taken as an example for illustration.

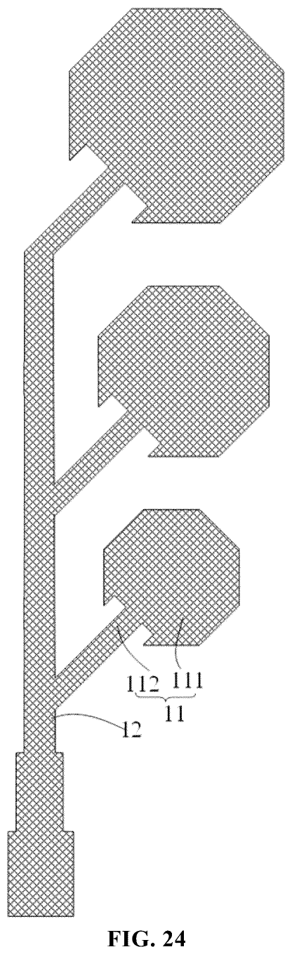

Fourth example: FIG. 24 is a top view of a log periodic antenna in a fourth example according to an embodiment of the present disclosure. As shown in FIG. 24, the log periodic antenna in this example has substantially the same structure as the log periodic antenna in the first example, except that in this example, the radiation structures 11 are connected to only one of the first side or the second side of the feed assembly 12, and FIG. 24 only takes the case where three radiation structures 11 are connected to the second side of the feed assembly 12 as an example for illustration.

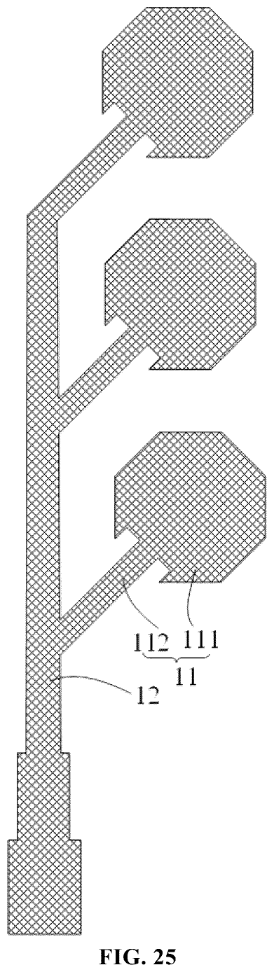

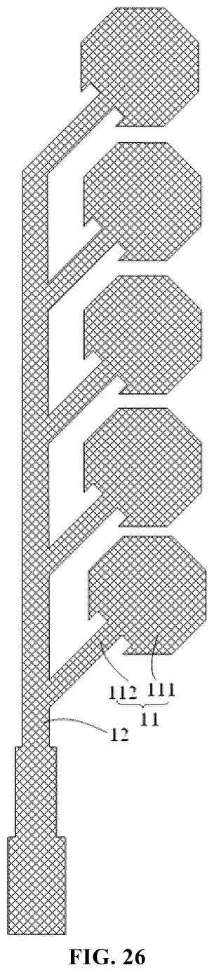

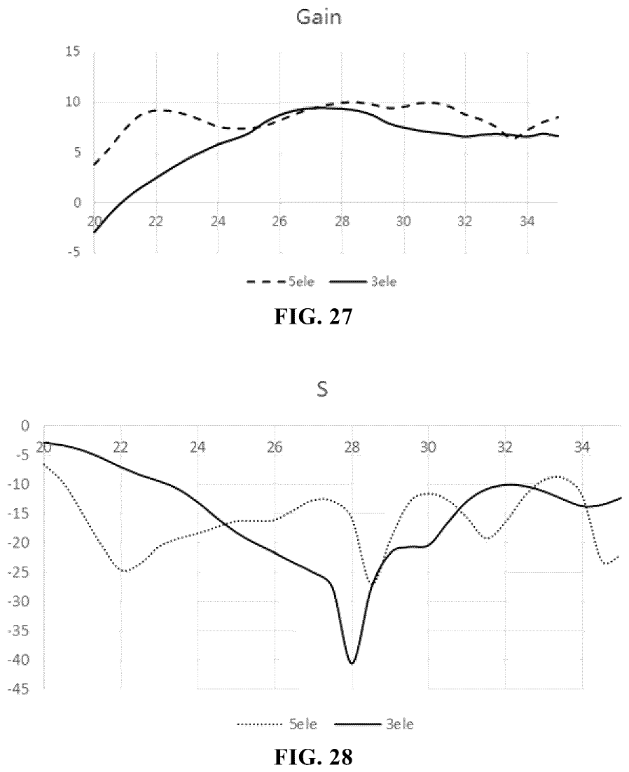

FIG. 25 is a top view of another antenna in the fourth example according to an embodiment of the present disclosure. As shown in FIG. 25, in this antenna structure, the radiation parts 111 of the respective radiation structures 11 may have the same size. FIG. 26 is a top view of yet another antenna in the fourth example according to an embodiment of the present disclosure; and FIG. 26 only takes the case where five radiation structures 11 are connected to the second side of the feed assembly 12 as an example for illustration. A log periodic antenna having three radiation structures 11 is compared with a log periodic antenna having five radiation structures 11. FIG. 27 shows gain curves for the antennas in FIGS. 25 and 26 according to an embodiment of the present disclosure; and FIG. 28 shows S parameter curves for the antennas in FIGS. 25 and 26 according to an embodiment of the present disclosure. It can be seen from FIGS. 27 and 28 that the log periodic antenna having five radiation structures 11 clearly maintains a stable gain over a very wide frequency band. It should be noted that even if the radiation parts 111 of the respective radiation structures 11 have the same size, the gain bandwidth of the antenna increases significantly as the number of radiation structures 11 increases.

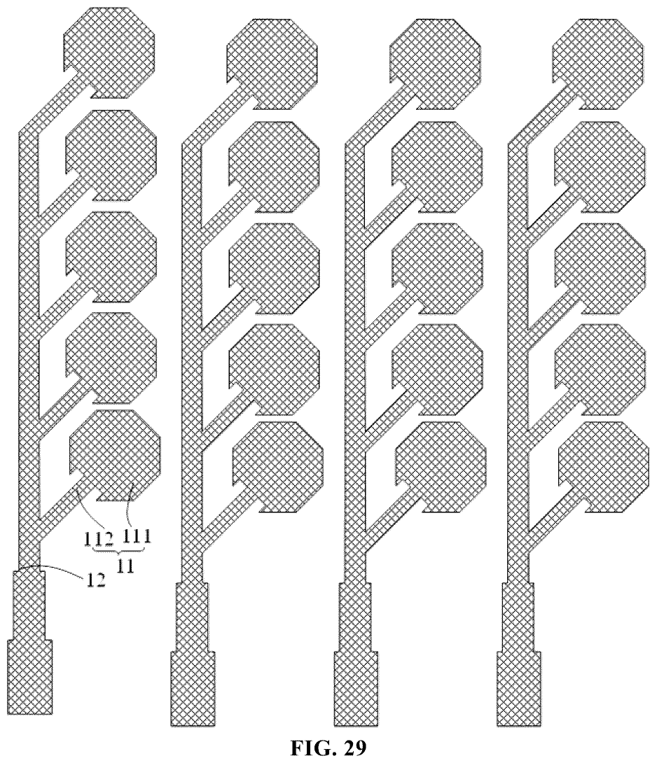

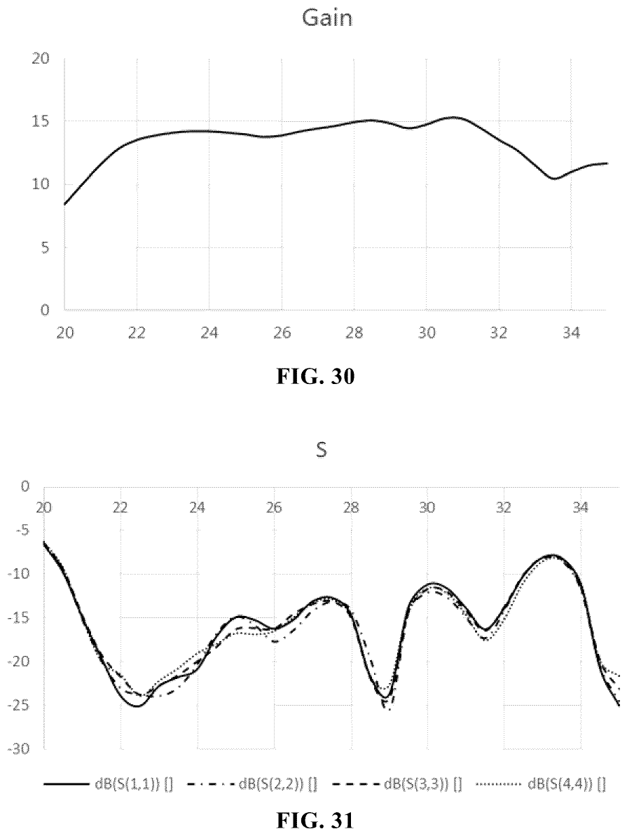

In some examples, FIG. 29 is a top view of an antenna module in the fourth example according to an embodiment of the present disclosure; FIG. 30 is a graph of gain for the antenna module in the fourth example according to an embodiment of the present disclosure; and FIG. 31 is a graph of S parameter for the antenna module in the fourth example according to an embodiment of the present disclosure. As shown in FIG. 29, when the log periodic antenna is applied to an antenna module, the antenna module may include a plurality of log periodic antennas, and in a case where the antenna module includes 1*4 log periodic antennas, the simulation results are shown in FIGS. 30 and 31.

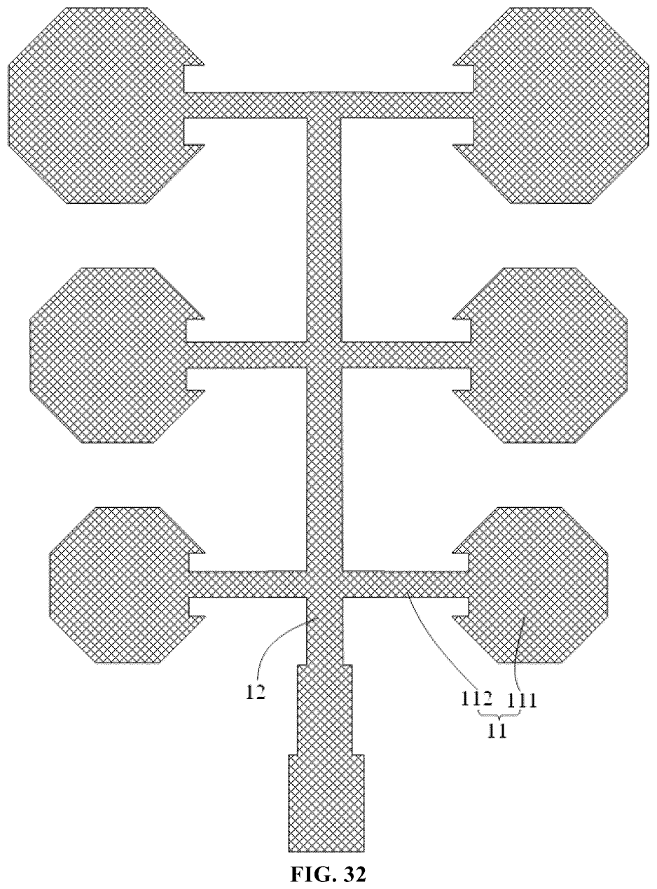

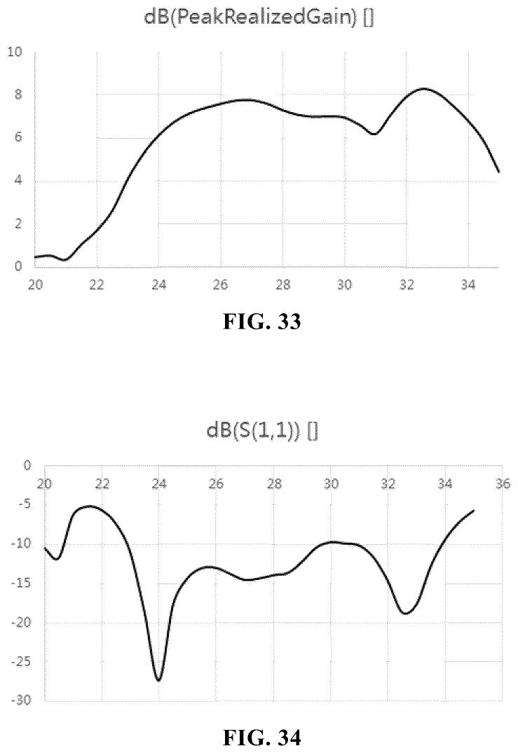

Fifth example: FIG. 32 is a top view of a log periodic antenna in a fifth example according to an embodiment of the present disclosure. As shown in FIG. 32, in a log periodic antenna according to this example, the radiation structures 11 are connected to both the first side and the second side of the feed assembly 12, the radiation structures 11 connected to the first side and the second side of the feed assembly 12 are arranged in one-to-one correspondence, and the radiation structures 11 in correspondence are connected to the feed assembly 12 at the same connection node. FIG. 33 shows an example where N=6 and M=3. In this example, feeders 112 of the radiation structures 11 have a single extending direction, which is perpendicular to an extending direction of the feed assembly 12. FIG. 33 is a top view of a log periodic antenna in the fifth example according to an embodiment of the present disclosure; and FIG. 34 is a graph of gain for a log periodic antenna in the fifth example according to an embodiment of the present disclosure. As shown in FIGS. 33 and 34, the simulation shows that this type of log periodic antenna has an S parameter substantially below −10 dB, and a gain around 7 dBi.

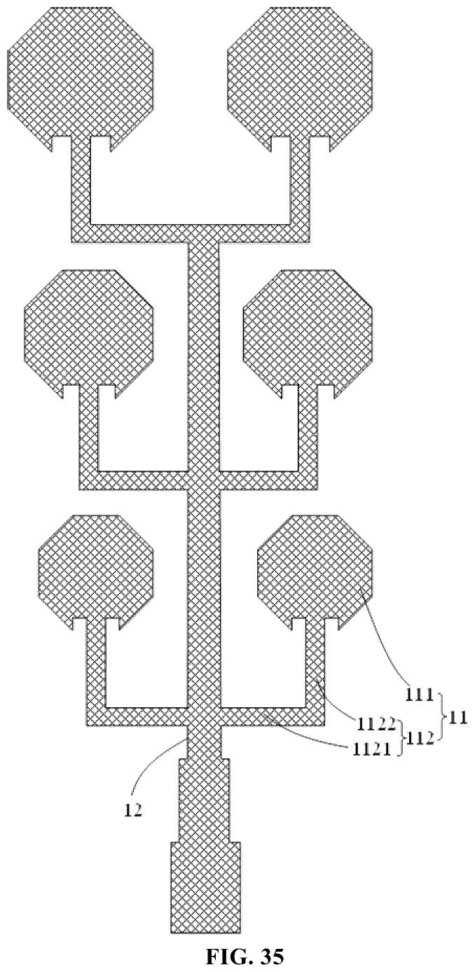

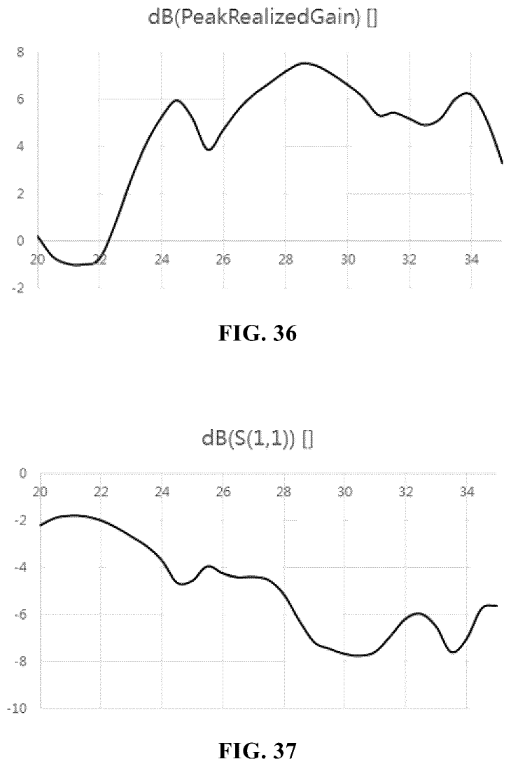

Sixth example: FIG. 35 is a top view of a log periodic antenna in a sixth example according to an embodiment of the present disclosure. As shown in FIG. 35, the log periodic antenna in this example has substantially the same structure as the log periodic antenna in the fifth example, except that the feeder 112 of the radiation structure 11 includes a first sub-feeder 1121 and a second sub-feeder 1122, and the first sub-feeder 1121 and the second sub-feeder 1122 have different extending directions. A first end of the first sub-feeder 1121 is connected to the feed assembly 12, a second end of the first sub-feeder 1121 is connected to a first end of the second sub-feeder 1122, and a second end of the second sub-feeder 1122 is connected to the radiation part 111. It can be seen that the polarization direction of the log periodic antenna in this example is different from that in the fifth example. Specifically, if the extending direction of the first sub-feeder 1121 is perpendicular to the extending direction of the feed assembly 12, and the extending direction of the second sub-feeder 1122 is parallel to the extending direction of the feed assembly 12, the log periodic antenna has a horizontal polarization direction. FIG. 36 is a graph of gain for a log periodic antenna in the sixth example according to an embodiment of the present disclosure; and FIG. 37 shows an S parameter for a log periodic antenna in the sixth example according to an embodiment of the present disclosure. As shown in FIGS. 36 and 37, the simulation shows that this type of log periodic antenna has an S parameter substantially below −10 dB, and a gain around 7 dBi.

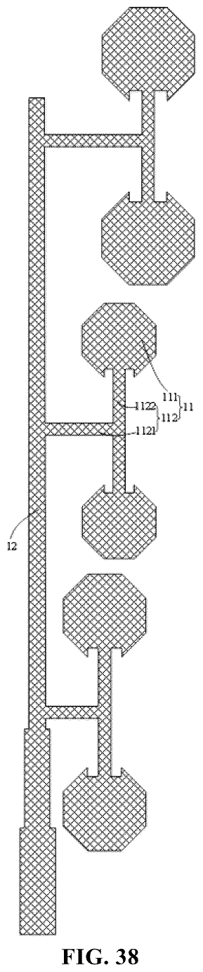

Seventh example: FIG. 38 is a top view of a log periodic antenna in a seventh example according to an embodiment of the present disclosure. As shown in FIG. 38, in a log periodic antenna according to this example, the radiation structures 11 are connected to only the second side of the feed assembly 12. Every two adjacent radiation structures 11 form a group in which the feeder 112 of each radiation structure 11 includes a first sub-feeder 1121 and a second sub-feeder 1122 which have different extending directions. A first end of the first sub-feeder 1121 is connected to the feed assembly 12, a second end of the first sub-feeder 1121 is connected to a first end of the second sub-feeder 1122, and a second end of the second sub-feeder 1122 is connected to the radiation part 111. The two radiation structures 11 share one first sub-feeder 1121, second sub-feeders 1122 of the two radiation structures 11 are symmetrically arranged taking an extending direction of the first sub-feeder 1121 as an axis of symmetry, and radiation parts 111 of the two radiation structures 11 have the same size. Radiation parts 111 of the respective groups of radiation structures 11 have gradually reduced sizes in a direction away from a feed port of the feed assembly 12, which satisfy a periodic variation. First sub-feeders 1121 of the respective groups of radiation structures 11 have gradually increased lengths in a direction away from the feed port of the feed assembly 12.

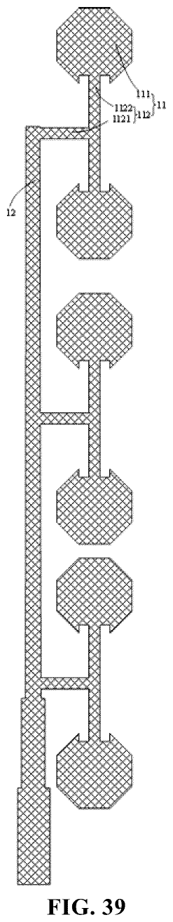

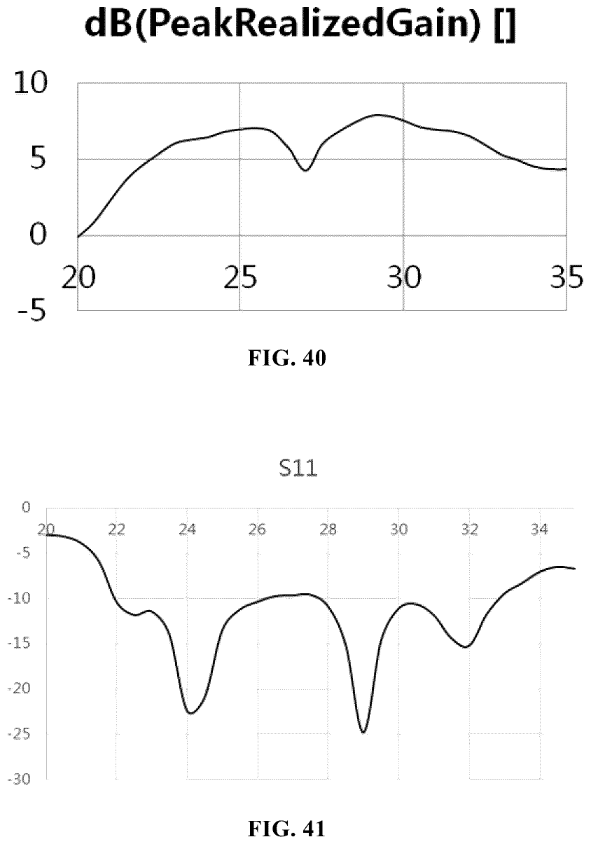

FIG. 39 is a top view of another log periodic antenna in the seventh example according to an embodiment of the present disclosure. As shown in FIG. 39, the first sub-feeders 1121 of the respective groups of radiation structures 11 may have the same length in the direction away from the feed port of the feed assembly 12. FIG. 40 is a top view of the log periodic antenna in FIG. 41 according to an embodiment of the present disclosure; and FIG. 41 is a graph of gain for the log periodic antenna in FIG. 41 according to an embodiment of the present disclosure. As shown in FIGS. 40 and 41, the simulation shows that this type of log periodic antenna has a S parameter substantially below −10 dB, and a gain around 7 dBi.

In some examples, the antenna module provided in the embodiments of the present disclosure further includes a transceiver unit, a radio frequency transceiver, a signal amplifier, a power amplifier, and a filter unit. The log periodic antenna in the antenna module may be used as a transmitting antenna or a receiving antenna. The transceiver unit may include a baseband and a receiving end. The baseband provides signals of at least one frequency band, for example, 2G signals, 3G signals, 4G signals, 5G signals, or the like, and transmits the signals of the at least one frequency band to the radio frequency transceiver. After being received by the log periodic antenna in the antenna system, the signals may be processed by the filter unit, the power amplifier, the signal amplifier, and the radio frequency transceiver, and then transmitted to the receiving end in the transceiver unit. The receiving end may be, for example, an intelligent gateway, or the like.

Furthermore, the radio frequency transceiver is connected to the transceiver unit, and configured to modulate a signal sent from the transceiver unit, or demodulate a signal received by the transparent antenna and transmit the demodulated signal to the transceiver unit. Specifically, the radio frequency transceiver may include a transmitting circuit, a receiving circuit, a modulation circuit, and a demodulation circuit. After being received by the transmitting circuit, multiple types of signals provided by the baseband can be modulated by the modulation circuit and then transmitted to the antenna. Then, the transparent antenna receives and transmits the signals to the receiving circuit of the radio frequency transceiver which further transmits the signals to the demodulation circuit, where the signals are demodulated by the demodulation circuit and then transmitted to the receiving end.

Further, the radio frequency transceiver is connected to the signal amplifier and the power amplifier which are further connected to the filter unit, and the filter unit is connected to at least one log periodic antenna. In the process of transmitting signals by the antenna system, the signal amplifier is configured to increase signal-to-noise ratio of signals output from the radio frequency transceiver, and then transmit the signals to the filter unit. The power amplifier is configured to amplify power of the signals output from the radio frequency transceiver, and then to transmit the signals to the filter unit. The filter unit may specifically include a duplexer and a filter circuit. The filter unit combines the signals output from the signal amplifier and the power amplifier, filters noise waves, and then transmits the signals to the log periodic antenna to be radiated. In the process of receiving signals by the antenna system, after being received by the log periodic antenna, the signals are transmitted to the filter unit, where the signals received by the antenna are filtered to remove noise waves by the filter unit and then transmitted to the signal amplifier and the power amplifier. The signal amplifier increases a gain of the signals received by the antenna to increase a signal-to-noise ratio of the signals; while the power amplifier amplifies a power of the signals received by the log periodic antenna. After being processed by the power amplifier and the signal amplifier, the signals received by the log periodic antenna are transmitted to the radio frequency transceiver, and then to the transceiver unit.

In some examples, the signal amplifier may include various types of signal amplifiers, such as a low noise amplifier, which is not limited herein.

In some examples, the antenna module provided in the embodiments of the present disclosure further includes a power management unit, which is connected to the power amplifier and provides a voltage for signal amplification for the power amplifier.

In some examples, the display apparatus may be, for example, a mobile phone, a tablet, a television, a monitor, a laptop, a digital album, a vehicle-mounted device or any other product having a display function. Other essential components of the display apparatus 200 are regarded as present by those skilled in the art, which are not described herein and should not be construed as limiting the present disclosure.

It will be appreciated that the above implementations are merely exemplary implementations for the purpose of illustrating the principle of the present disclosure, and the present disclosure is not limited thereto. It will be apparent to those skilled in the art that various modifications and variations may be made without departing from the spirit or essence of the present disclosure. Such modifications and variations should also be considered as falling into the protection scope of the present disclosure.

1. A log periodic antenna, comprising a feed assembly and N radiation structures; wherein the radiation structures are electrically connected to the feed assembly at M connection nodes, respectively; where N≥3, and M≥3; wherein distances between the M connection nodes satisfy a periodic variation.

2. The log periodic antenna according to claim 1, wherein each radiation structure comprises a radiation part and a feeder, the radiation part has a notch, and the feeder has one end within the notch and electrically connected to the radiation part, and the other end electrically connected to the feed assembly.

3. The log periodic antenna according to claim 2, wherein the notch has a first side electrically connected to the feeder, and a second side and a third side connected to two ends of the first side, and the second side and the third side have the same extending direction as the feeder, and are perpendicular to the first side.

4. The log periodic antenna according to claim 2, wherein the radiation part has a generally regular octagonal outline.

5. The log periodic antenna according to claim 1, wherein the feed assembly has a first side and a second side opposite to each other, and the radiation structures are connected to both the first side and the second side of the feed assembly.

6. The log periodic antenna according to claim 5, wherein each radiation structure comprises a radiation part and a feeder, and the radiation part is electrically connected to the feed assembly by the feeder; and
respective radiation structures are connected to the feed assembly at different connection nodes, and radiation parts of the respective radiation structures have gradually reduced sizes in a direction away from a feed port of the feed assembly, which gradually reduced sizes satisfy a periodic variation.

7. The log periodic antenna according to claim 5, wherein the radiation structures connected to the first side and the second side of the feed assembly are arranged in one-to-one correspondence, and the radiation structures in correspondence are connected to the feed assembly at the same connection node; each radiation structure comprises a radiation part and a feeder, and the radiation part is electrically connected to the feed assembly by the feeder; and
radiation parts of the radiation structures in correspondence have the same size; radiation parts of the respective radiation structures connected to the first side of the feed assembly have gradually reduced sizes in a direction away from a feed port of the feed assembly, and satisfy a periodic variation; and radiation parts of the respective radiation structures connected to the second side of the feed assembly have gradually reduced sizes in a direction away from a feed port of the feed assembly, which gradually reduced sizes satisfy a periodic variation.

8. The log periodic antenna according to claim 7, wherein the feeder has a single extending direction which is intersected with an extending direction of the feed assembly.

9. The log periodic antenna according to claim 7, wherein the feeder comprises a first sub-feeder and a second sub-feeder which have different extending directions; wherein a first end of the first sub-feeder is connected to the feed assembly, a second end of the first sub-feeder is connected to a first end of the second sub-feeder, and a second end of the second sub-feeder is connected to the radiation part.

10. The log periodic antenna according to claim 1, wherein the feed assembly has a first side and a second side opposite to each other, and the radiation structures are connected to either the first side or the second side of the feed assembly.

11. The log periodic antenna according to claim 10, wherein each radiation structure comprises a radiation part and a feeder, and the radiation part is electrically connected to the feed assembly by the feeder; and
respective radiation structures are connected to the feed assembly at different connection nodes, and radiation parts of the respective radiation structures have gradually reduced sizes in a direction away from a feed port of the feed assembly, which gradually reduced sizes satisfy a periodic variation.

12. The log periodic antenna according to claim 10, wherein each radiation structure comprises a radiation part and a feeder, the radiation part is electrically connected to the feed assembly by the feeder;
every two adjacent radiation structures form a group in which the feeder of each radiation structure comprises a first sub-feeder and a second sub-feeder which have different extending directions; a first end of the first sub-feeder is connected to the feed assembly, a second end of the first sub-feeder is connected to a first end of the second sub-feeder, and a second end of the second sub-feeder is connected to the radiation part; and the two radiation structures share one first sub-feeder, second sub-feeders of the two radiation structures are symmetrically arranged taking an extending direction of the first sub-feeder as an axis of symmetry, and radiation parts of the two radiation structures have the same size; and
radiation parts of respective groups of radiation structures have gradually reduced sizes in a direction away from a feed port of the feed assembly, which gradually reduced sizes satisfy a periodic variation.

13. The log periodic antenna according to claim 12, wherein first sub-feeders of the respective groups of radiation structures have gradually increased lengths in the direction away from the feed port of the feed assembly.

14. The log periodic antenna according to claim 1, wherein a feed port of the feed assembly comprises a first sub-structure, a second sub-structure, and a third sub-structure connected in sequence; and the second sub-structure is configured to match an impedance of the first sub-structure with an impedance of the third sub-structure.

15. A display apparatus, comprising a display module, and an antenna module on a light-emitting surface side of the display module; wherein the antenna module comprises at least one log periodic antenna according to claim 1.

16. The display apparatus according to claim 15, wherein the antenna module comprises a radiation layer; wherein the radiation layer has a metal mesh structure, and the log periodic antenna is in the radiation layer.

17. The display apparatus according to claim 16, wherein the radiation layer further comprises a redundant radiation structure.

18. The display apparatus according to claim 15, further comprising a polarizer, wherein the antenna module is on a side of the polarizer close to the display module.

19. The display apparatus according to claim 15, further comprising a touch module between the display module and the antenna module.

20. The display apparatus according to claim 15, wherein the display module is an organic light-emitting diode display module.
